(19) United States
(12) Patent Application Publication
(10) Pub. No.: US 2014/0264484 A1
(43) Pub. Date: Sep. 18, 2014

(54) FLUORINE-DOPED CHANNEL SILICON-GERMANIUM LAYER

(71) Applicants: Nicolas SASSIAT, Dresden (DE); Ran Yan, Dresden (DE); Jan Hoentschel, Dresden (DE); Shiang Yang Ong, Singapore (SG)

(72) Inventors: Nicolas SASSIAT, Dresden (DE); Ran Yan, Dresden (DE); Jan Hoentschel, Dresden (DE); Shiang Yang Ong, Singapore (SG)

(73) Assignee: GLOBALFOUNDRIES Singapore Pte. Ltd., Singapore (SG)

(21) Appl. No.: 13/832,495

(22) Filed: Mar. 15, 2013

(51) Int. Cl. H01L 21/265; H01L 29/66; H01L 29/78

(52) U.S. Cl. CPC H01L 21/26513; H01L 29/78; H01L 29/66568
USPC 257/288; 438/285

(57) ABSTRACT

Methods for forming P-type channel metal-oxide-semiconductor field effect transistors (PMOSFETs) with improved interface roughness at the channel silicon-germanium (cSiGe) layer and the resulting devices are disclosed. Embodiments may include designating a region in a substrate as a channel region, forming a cSiGe layer above the designated channel region, and implanting fluorine directly into the cSiGe layer. Embodiments may alternatively include implanting fluorine into a region in a silicon substrate designated a channel region, forming a cSiGe layer above the designated channel region, and heating the silicon substrate and the cSiGe layer to diffuse the fluorine into the cSiGe layer.

### TECHNICAL FIELD

The present disclosure relates to channel silicon-germanium (cSiGe) layers in semiconductor devices. The present disclosure is particularly applicable to forming thin cSiGe layers with improved interface roughness while maintaining threshold voltage efficiency in p-channel metal-oxide-semiconductor field effect transistors (PMOSFETs).

### BACKGROUND

Using cSiGe layers in PMOSFETs for high-k dielectric metal gate technology can reduce the threshold voltage. Yet, the thickness required to reduce the threshold voltage, e.g., 100 angstroms (Å) or greater, increases the interface roughness between the cSiGe layer and other layers (e.g., silicon substrate and/or gate dielectric layer). The increase in interface roughness degrades reliability and performance of the transistor.

A need therefore exists for methodology enabling thinner cSiGe layers with improved interface roughness while maintaining efficient threshold voltages, and the resulting device.

### SUMMARY

An aspect of the present disclosure is an efficient method for forming a fluorine-doped cSiGe layer in a PMOSFET.

Another aspect of the present disclosure is a PMOSFET with a fluorine-doped cSiGe layer.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: designating a region in a substrate as a channel region, forming a cSiGe layer above the designated channel region, and implanting fluorine directly into the cSiGe layer.

An aspect of the present disclosure includes implanting the fluorine in the cSiGe layer at a dose of 8×10¹⁴ to 2×10¹⁵ atoms/cm². Another aspect of the present disclosure is implanting the fluorine in the cSiGe layer at an energy of 5 to 10 kiloelectron volts (keV). Yet another aspect of the present disclosure is annealing the cSiGe layer at 400 to 650° C. after implanting the fluorine. An additional aspect of the present disclosure is forming the cSiGe layer to a thickness of 40 to 80 Å. Another aspect of the present disclosure is forming a gate dielectric layer over the cSiGe layer. An additional aspect of the present disclosure is forming a gate on the gate dielectric layer.

Further technical effects also may be achieved in part by a method including: implanting fluorine into a region in a silicon substrate designated a channel region, forming a cSiGe layer above the designated channel region, and heating the silicon substrate and the cSiGe layer to diffuse the fluorine into the cSiGe layer.

Another aspect includes implanting the fluorine in the designated channel region at a dose of 1×10¹⁵ to 3×10¹⁵ atoms/cm². An additional aspect includes implanting the fluorine in the designated channel region at an energy of 5 to 10 keV. Yet another aspect includes annealing the silicon substrate at 650 to 1050° C. after implanting the fluorine and prior to forming the cSiGe layer. A further aspect includes forming the cSiGe layer to a thickness of 40 to 80 Å. Other aspects include forming a gate dielectric layer over the cSiGe layer, wherein the heating of the silicon substrate and the cSiGe layer occurs during and/or after forming the gate dielectric layer. Further aspects include forming a gate on the gate dielectric layer, wherein the heating of the silicon substrate and the cSiGe layer occurs during and/or after forming the gate.

Another aspect of the present disclosure is a device including: a substrate, a P-type channel region in the substrate, and a fluorine-doped cSiGe layer above the P-type channel region on the substrate, with the cSiGe layer formed to a thickness of 40 to 80 Å.

Aspects include the fluorine implanted at an energy of 5 to 10 keV. Additional aspects include the fluorine implanted at a dose of 1×10¹⁵ to 3×10¹⁵ atoms/cm² and annealed at 650 to 1050° C. Further aspects include the fluorine implanted at a dose of 8×10¹⁴ to 2×10¹⁵ atoms/cm² and annealed at 400 to 650° C. Yet another aspect includes a gate dielectric layer above the cSiGe layer. Another aspect includes a high-k dielectric metal gate above the gate dielectric layer.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1 through 4 schematically illustrate a method for forming a fluorine-doped cSiGe layer in a PMOSFET, in accordance with an exemplary embodiment; and

FIGS. 5 through 7 schematically illustrate a method for forming a fluorine-doped cSiGe layer in a PMOSFET, in accordance with an alternative exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of poor performance and reliability attendant upon forming cSiGe layers to a sufficient thickness to reduce threshold voltage in PMOSFETs. In accordance with embodiments of the present disclosure, a fluorine-doped cSiGe layer is formed within a PMOSFET with a reduced thickness to improve device reliability and performance while maintaining an efficient threshold voltage.

Methodology in accordance with an embodiment of the present disclosure includes designating a region in a substrate as a channel region. Next, a cSiGe layer is formed above the designated channel region. The cSiGe layer may be formed to a thickness of 40 to 80 Å. Next, fluorine is directly implanted into the cSiGe layer. Subsequent steps may include forming a gate dielectric layer and a gate over the cSiGe layer.

Methodology in accordance with another embodiment of the present disclosure includes implanting fluorine into a region in a silicon substrate designated a channel region. Next, a cSiGe layer is formed above the designated channel region. The cSiGe layer may be formed to a thickness of 40 to 80 Å. Subsequently, the silicon substrate and the cSiGe layer are heated to diffuse the fluorine into the cSiGe layer.

Adverting to FIG. 1, a method for forming a fluorine-doped cSiGe layer in a PMOSFET, according to an exemplary embodiment, begins with a substrate 101. The substrate 101 may be a bulk silicon (Si) wafer, as illustrated. Alternatively, the substrate 101 may be a silicon-on-insulator (SOI) wafer. The substrate may include a region 103 that, after subsequent processing discussed below, will become a channel region.

Next, a cSiGe layer 201 is formed over the substrate 101, as illustrated in FIG. 2. The cSiGe layer 201 may be formed to a thickness of 40 to 80 Å and may be formed according to conventional processing techniques, such as by epitaxial growth.

Subsequently, fluorine is implanted directly into the cSiGe layer 201 to form a fluorine-doped cSiGe layer 301, as illustrated in FIG. 3. The fluorine may be implanted at a dose of 8×10¹⁴ to 2×10¹⁵ atoms/cm² and an energy of 5 to 10 keV. The implanted fluorine allows for a reduced threshold voltage of the resulting PMOSFET and allows for a thinner cSiGe layer. After implanting the fluorine, the cSiGe layer 301 is annealed at 400 to 650° C. for 4 minutes to heal any implantation damage as a result of implanting the fluorine directly into the cSiGe layer 201.

Subsequently, a gate dielectric layer 401, gate 403, and spacers 405 are formed over the fluorine-doped cSiGe layer 301, as illustrated in FIG. 5. Source/drain regions 407 are then formed, with a channel region 409 formed where the region 103 was previously located under the gate 403 and between the source/drain regions 407, forming a PMOSFET. The fluorine-doped cSiGe layer 301 may be etched to be the width of the gate 403, as illustrated by the etched fluorine-doped cSiGe layer 411. The gate dielectric layer 401 may be a high-k dielectric, such as nitride hafnium silicate (HfSiON), and the gate 403 may be a metal gate.

The thinner fluorine-doped cSiGe layer 301/411 results in less interface roughness than a conventional, thicker (e.g., 100 Å or greater), non-fluorine-doped cSiGe layer that provides an equivalent threshold voltage. The thinner fluorine-doped cSiGe layer 301/411 also allows for less interface charge trapping and de-trapping and a higher device mobility. Further, controlling the fluorine implantation is easier than controlling the growth of the SiGe on the surface of the substrate 101. The reduced thickness of the cSiGe, in addition to the properties of fluorine consuming charged oxygen vacancies, such as in an oxidation layer that forms on the top of the SiGe (e.g., SiₓGe_{y}O_{z}) or in a subsequently formed high-k dielectric layer, improves reliability and performance of the resulting PMOSFET. For example, the fluorine-doped cSiGe layer 301/411 improves the maximum voltage supplied (V_{DDMAX}) by 25 to 70 millivolts (mV) and the time-dependent dielectric breakdown voltage (TDDB) by 20 to 40 mV over conventional, non-fluorine-doped cSiGe layers.

Adverting to FIG. 5, a method for forming a fluorine-doped cSiGe layer in a PMOSFET, according to another exemplary embodiment, begins with the substrate 101 with the region 103 of FIG. 1. Next, fluorine is implanted into the top surface of the substrate 101 within the region 103 forming a fluorine-doped layer 501, as illustrated in FIG. 5. The fluorine may be implanted into the substrate 101 at a dose of 1×10¹⁵ to 3×10¹⁵/cm² and an energy of 5 to 10 keV. At this dose, the fluorine allows for a reduced threshold voltage of the resulting PMOSFET and allows for a thinner cSiGe layer. After implanting the fluorine, the substrate 101 is annealed at 650 to 1050° C. for 5 to 240 seconds, depending on the temperature, to heal any damage caused by the fluorine implantation.

Next, a cSiGe layer 201 is formed over the substrate 101, as illustrated in FIG. 6. The cSiGe layer 201 may be formed to a thickness of 40 to 80 Å and may be formed according to conventional processing techniques, such as by epitaxial growth. The implanted fluorine within the substrate 101 also reduces the SiGe growing rate, allowing for a thinner cSiGe layer 201.

Subsequently, additional processing steps may be performed, such as forming a gate dielectric layer 401, the gate 403, and the spacers 405 over the cSiGe layer 201, as illustrated in FIG. 7. Other processing steps may be performed to form source/drain regions 407, with a channel region 409 formed where the region 103 was previously located under the gate 403 and between the source/drain regions 407, forming a PMOSFET. Any subsequent processing step that involves heating the substrate 101 will cause the fluorine in the fluorine-doped layer 501 to diffuse into the cSiGe layer 201 to create a fluorine-doped cSiGe layer, which may be further masked and etched to form the fluorine-doped cSiGe layer 701 with a narrower width, as illustrated in FIG. 7. Any subsequent heating will also further heal the interface damage of the substrate 101 caused by the fluorine implantation.

The embodiments of the present disclosure achieve several technical effects, including maintaining efficient threshold voltage while reducing interface roughness between a cSiGe layer and additional layers (e.g., Si substrate and gate dielectric layer) in a PMOSFET, thereby improving performance and reliability of the transistor. Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
designating a region in a substrate as a channel region;
forming a channel silicon-germanium (cSiGe) layer above the designated channel region; and
implanting fluorine directly into the cSiGe layer.

2. The method according to claim 1, comprising implanting the fluorine in the cSiGe layer at a dose of 8×10¹⁴ to 2×10¹⁵ atoms/centimeter² (cm²).

3. The method according to claim 1, comprising implanting the fluorine in the cSiGe layer at an energy of 5 to 10 kiloelectron volts (keV).

4. The method according to claim 1, further comprising annealing the cSiGe layer at 400 to 650° C. after implanting the fluorine.

5. The method according to claim 1, comprising forming the cSiGe layer to a thickness of 40 to 80 Angstroms (Å).

6. The method according to claim 1, further comprising forming a gate dielectric layer over the cSiGe layer.

7. The method according to claim 6, further comprising forming a gate on the gate dielectric layer.

8. A method comprising:
implanting fluorine into a region in a silicon substrate designated a channel region;
forming a channel silicon-germanium (cSiGe) layer above the designated channel region; and
heating the silicon substrate and the cSiGe layer to diffuse the fluorine into the cSiGe layer.

9. The method according to claim 8, comprising implanting the fluorine in the designated channel region at a dose of 1×10¹⁵ to 3×10¹⁵ atoms/centimeter² (cm²).

10. The method according to claim 8, comprising implanting the fluorine in the designated channel region at an energy of 5 to 10 kiloelectron volts (keV).

11. The method according to claim 8, further comprising annealing the silicon substrate at 650 to 1050° C. after implanting the fluorine and prior to forming the cSiGe layer.

12. The method according to claim 8, comprising forming the cSiGe layer to a thickness of 40 to 80 Angstroms (Å).

13. The method according to claim 8, further comprising:
forming a gate dielectric layer over the cSiGe layer,
wherein the heating of the silicon substrate and the cSiGe layer occurs during and/or after forming the gate dielectric layer.

14. The method according to claim 13, further comprising:
forming a gate on the gate dielectric layer,
wherein the heating of the silicon substrate and the cSiGe layer occurs during and/or after forming the gate.

15. A device comprising:
a substrate;
a P-type channel region in the substrate; and
a fluorine-doped channel silicon-germanium (cSiGe) layer above the P-type channel region on the substrate, the cSiGe layer formed to a thickness of 40 to 80 Angstroms (Å).

16. The device according to claim 15, wherein the fluorine is implanted at an energy of 5 to 10 kiloelectron volts (keV).

17. The device according to claim 16, wherein the fluorine is implanted at a dose of 1×10¹⁵ to 3×10¹⁵ atoms/centimeter² (cm²) and annealed at 650 to 1050° C.

18. The device according to claim 16, wherein the fluorine is implanted at a dose of 8×10¹⁴ to 2×10¹⁵ atoms/centimeter² (cm²) and annealed at 400 to 650° C.

19. The device according to claim 15, further comprising a gate dielectric layer above the cSiGe layer.

20. The device according to claim 19, further comprising a metal gate above the gate dielectric layer.
